(19) United States
(12) Patent Application Publication
(10) Pub. No.: US 2022/0408583 A1
(43) Pub. Date: Dec. 22, 2022

(54) ENCAPSULATION ASSEMBLY FOR GLASS, ENCAPSULATED GLASS AND MANUFACTURING METHOD THEREOF

(71) Applicant: SAINT-GOBAIN GLASS FRANCE, COURBEVOIE (FR)

(72) Inventors: Siteng MA, SHANGHAI (CN); Louis THIERRY, MANIQUERVILLE (FR)

(21) Appl. No.: 17/763,546

(22) PCT Filed: Sep. 23, 2020
(86) PCT No.: PCT/CN2020/117058

§ 371 Date: Mar. 24, 2022

(30) Foreign Application Priority Data
Sep. 25, 2019 (CN) 201910910659.3

(51) Int. Cl. H05K 5/06; B29C 45/14; B29C 45/00

(52) U.S. Cl. CPC H05K 5/065; B29C 45/14467; B29C 45/14434; B29C 45/0053; B29C 2045/14868; B29K 2021/003

(57) ABSTRACT

An encapsulation assembly includes a body located at edges of the functional glass; and a conductive module embedded in the body or located on a surface of the body, and electrically connected to a functional module on the functional glass. The process of forming an encapsulated glass from the encapsulation assembly for a functional glass can omit complicated manufacturing steps and save materials and thus reduce costs. An easy and stable control of the functional module in the glass can also be accomplished. Moreover, it is much easier to form an encapsulated glass from the glass, which facilitates glass mounting.

### FIELD

Embodiments of the present disclosure generally relate to an encapsulated glass, and more specifically, to an encapsulation assembly for glass and a manufacturing method of the encapsulated glass.

### BACKGROUND

In pace with the continuous development of industry (e.g. auto industry), there arises a need for integrating more and more functions in glass. For example, some automobile glass is integrated with a color-changing or a transparency-adjustment function to adjust a color and transparency of glass according to a change of the ambient environment (e.g., temperature or the like). There is also some glass integrated with the functions such as lighting, display, touch, antenna, heating, or the like. For the glass integrated with a color-changing or a transparency-adjustment function, currently some automobile glass employs Polymer Dispersed Liquid Crystal (PDLC) in arranging in laminated glass. Since the PDLC has a characteristic of an electrochromic or an electrically induced transparency, with the laminated glass using PDLC, the transparency of the laminated glass can be adjusted by controlling control parameters such as voltage and the like applied to the PDLC layer through a chip, so as to accomplish purposes of privacy protection or the like.

Nowadays, an electronic part (e.g., a chip) for controlling a functional module, such as PDLC or the like, is typically arranged on a circuit board independent of an encapsulated glass. The circuit board is connected to the functional module of the glass, an external power source module and an external data module via complicated wiring or connectors.

### SUMMARY

The conventional encapsulation assembly for glass with an electronic part has problems such as complicated wiring, difficulty in assembling and processing, or the like. The embodiments of the present disclosure provide an encapsulation assembly for glass, to solve or at least partly solve the above problems and other potential problems in the conventional encapsulation assembly of glass.

In a first aspect of the present disclosure, an encapsulation assembly for glass is provided. The encapsulation assembly comprises: a body located at edges of the functional glass; and a conductive module embedded in the body or located on a surface of the body, and electrically connected to a functional module on the functional glass.

In some embodiments, the conductive module comprises a conductive trace and a polymer matrix, and the conductive trace is formed on the polymer matrix.

In some embodiments, the conductive module comprises an interface coupled to the functional module, an external power module, an external signal module, and/or an electronic part.

In some embodiments, the interface comprises a connector or an interface circuit.

In some embodiments, the encapsulation assembly further comprises an electronic part electrically connected to the functional module via the conductive module to allow a control of functions of the functional module.

In some embodiments, the electronic part is arranged on the body or the polymer matrix through a Surface Mount Technology or a Dual In-line Packaging technology to be electrically connected with the conductive trace.

In some embodiments, the electronic part comprises at least one of the followings: a microcontroller, a voltage converter, and/or a bus transceiver.

In some embodiments, the voltage converter comprises a Direct Current converter or a Direct Current Alternating Current converter.

In some embodiments, the bus transceiver comprises at least one of a controller area network bus transceiver and a local interconnection network bus transceiver.

In some embodiments, the body is formed by injection molding.

In some embodiments, the body is made of at least one of a thermoplastic elastomer material, a polyvinyl chloride material or polyurethane, Acrylonitrile-butadiene-styrene plastic, a polypropylene, a polyethylene terephthalate, an ethylene propylene rubber, and a thermoplastic vulcanizate material.

In a second aspect of the present disclosure, an encapsulated glass is provided. The encapsulated glass comprises: a functional glass comprising a functional module arranged therein or thereon; and an encapsulation assembly of the first aspect, attached to the functional glass to form the encapsulated glass.

In some embodiments, the functional module is used to provide at least one of the following functions: color change, transparency adjustment, lighting, display, touch, photovoltaic power generation, heating or communication.

In a third aspect of the present disclosure, a manufacturing method of an encapsulated glass is provided. The manufacturing method comprises: providing a functional glass and a conductive module, the functional glass comprising a functional module, and the conductive module used for electrical connection with the functional module; arranging the functional glass at an appropriate position of a mold; arranging the conductive module in the mold so as to be subsequently embedded in a body formed by injection molding or located on a surface of the body formed by injection molding; and forming the body by injection molding.

In some embodiments, the step of providing the conductive module comprises forming a conductive trace on a polymer matrix.

In some embodiments, the manufacturing method further comprises, before forming the body at edges of the glass, electrically connecting an electronic part with the conductive module.

In some embodiments, the manufacturing method further comprises, after forming the body at edges of the glass, electrically connecting an electronic part with the conductive module.

This Summary is provided to introduce a selection of concepts in a simplified form that are further described below in the Detailed Description. This Summary is not intended to identify key features or essential features of the present disclosure, nor is it intended to be used to limit the scope of the present disclosure.

### BRIEF DESCRIPTION OF THE DRAWINGS

The above and other objectives, features, and advantages of the present disclosure will become more apparent, through the following detailed description of the example embodiments of the present disclosure with reference to the accompanying drawings in which the same reference symbols generally refer to the same elements.

FIG. 1 illustrates a perspective view of encapsulated glass according to embodiments of the present disclosure;

FIG. 2 illustrates a schematic diagram of a conductive module according to embodiments of the present disclosure; and

FIG. 3 illustrates a flowchart of a manufacturing method of encapsulated glass according to embodiments of the present disclosure.

Throughout the drawings, the same or similar reference symbols refer to the same or similar elements.

### DETAILED DESCRIPTION OF EMBODIMENTS

The present disclosure will now be described in detail with reference to several example embodiments. It should be appreciated that those embodiments of the present disclosure are provided to enable those skilled in the art to better understand and thus carry out the present disclosure, without suggesting any limitation to the scope of the technical solution of the present disclosure.

As used herein, the term “includes” and its variants are to be read as open-ended terms that mean “includes, but is not limited to.” The term “based on” is to be read as “based at least in part on.” The term “an embodiment” and “the embodiment” are to be read as “at least one embodiment.” The term “another embodiment” is to be read as “at least another embodiment.” The terms “first,” “second,” and the like may refer to different or the same objects. Other definitions, either explicit or implicit, may be included below. Definitions of terms are consistent throughout the specification unless the context clearly indicates otherwise.

The use of glass with an encapsulation assembly (i.e., an encapsulated glass), more often applied to vehicles (e.g., an automobile, train, or aircraft), is a current trend in technological development. The encapsulated glass cannot only provide good sealing performance and facilitate assembling of the glass, but also can maintain a desired bonding strength after assembling. In addition, the encapsulated glass has advantages of convenient replacement when it needs to be replaced.

For example, with the continuous development of technologies, glass is provided with various additional functions. For example, in a situation where privacy protection is required, it is expected to provide glass whose transparency can be adjusted as required. Glass may also be provided with a color-changing layer to form laminated glass which can adjust color according to needs. In addition to the above-mentioned functions, glass may be integrated with other functions, such as lighting, display, touch, antenna, photovoltaic power generation, heating, and the like. In addition, some glass is integrated with a sensing member (e.g., a sensor and the like) for sensing pressure, temperature or the like.

To attain these functions, extra electronic parts are required to be connected to functional modules in the glass and external modules, such as a power source, data module, or the like, outside the glass. These electronic parts are typically arranged on a circuit board independent of the encapsulated glass. The circuit board connects the functional modules of the glass with the external power source or control module through complicated wiring.

For example, conventional solutions include using a flat metal connector to connect an electrical input for controlling a functional module of the glass to an electronic control unit of an automobile, which probably needs a welding connection for the connector. On the one hand, the solutions using the connector result in a bulky encapsulation structure. On the other hand, the conventional solutions require extra materials and extra processes, such as welding and the like. In addition, this type of solutions also hinders manufacturing of encapsulated glass.

Moreover, the complicated wiring involved therein further increases the mounting difficulty during installation of the glass and thus impacting the mounting efficiency. Since such wiring is independent of encapsulated glass, it is prone to problems such as wire breakage when assembling the glass, which causes a poor user experience.

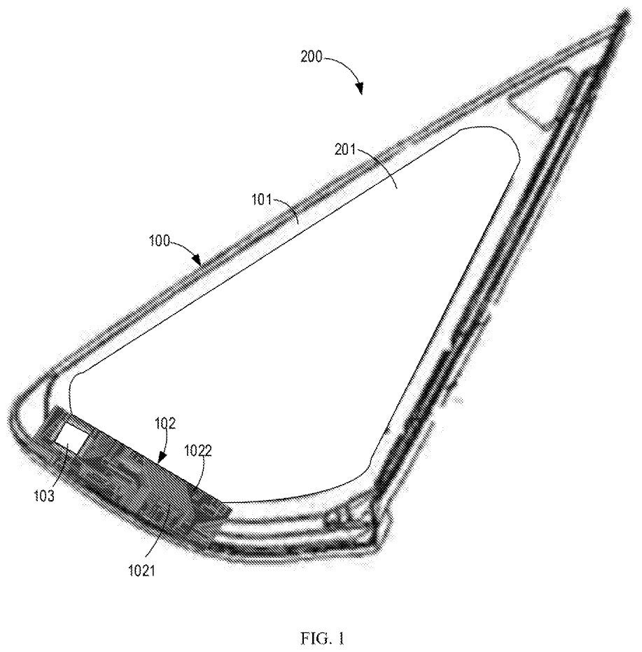

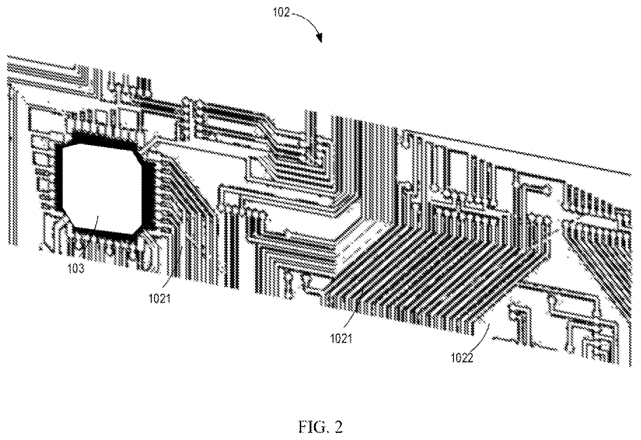

Embodiments of the present disclosure provide an encapsulation assembly 100 for functional glass and integrating a conductive module 102 in a body 101 of the encapsulation assembly 100 to solve or at least partly solve the foregoing problems and/or other potential problems of the conventional encapsulation assembly and encapsulated glass. Some example embodiments will now be described with reference to FIGS. 1 to 2.

As shown in FIG. 1, the encapsulation assembly 100 for glass according to embodiments of the present disclosure generally comprises a body 101 located at edges of the functional glass 201, and a conductive module 102. The functional glass 201 used herein may be glass on a vehicle, such as door glass, sunroof glass, corner window glass and/or windshield glass of an automobile, or the like. It should be appreciated that the functional glass 201 may be glass applied to other industries or technologies. The functional glass 201 comprises a functional module. For example, in some embodiments, the functional glass 201 may be laminated glass, and the functional module may be sandwiched between two layers of glass. Of course, in some alternative embodiments, the functional glass 201 may also be a tempered glass, and the functional module is attached onto a surface of the glass. The functional module may provide at least one of the following functions, including: color changing, transparency adjustment or heating.

Of course, it should be appreciated that the above embodiments about at least one of the plurality of functions provided by the functional module are merely for illustrative purposes, without suggesting any limitation as to the scope of the present disclosure. Any other appropriate module or arrangement is feasible. For example, in some alternative embodiments, the functional module may also be a module for providing a communication function arranged outside or on the glass.

In some other alternative embodiments, the functional module in the functional glass 201 may be used to provide functions such as display (e.g., by an LCD screen), lighting, touch, photovoltaic power generation, or the like. In addition to being applied to vehicles, the functional glass of the present disclosure may further be architectural glass, showcase glass, liquid crystal glass employed in electronic products, or the like. In addition, various functions provided by the functional module, as aforementioned, may be implemented by various layers, modules or sensors between layers of glass or on glass surfaces. It should be appreciated that any other module that is suitable to be arranged on glass to implement various functions is covered by the scope of the present disclosure.

The encapsulation assembly for functional glass may be formed at edges of the functional glass 201 by injection molding, the specific processes of which will be further illustrated below. However, it should be appreciated that the encapsulation assembly 100 for the functional glass 201 may be formed in advance and then attached to the glass 201 through adhesion, a snap-fit connection, or the like, to form encapsulated glass. Furthermore, the edges used herein may refer to adjacency of a boundary of an extending surface of the glass in a narrow sense. In some alternative embodiments, the edges may refer to any position on the outer contour of the glass in a broad sense, for example, any position adjacent to a boundary of an extending surface of the glass, to a center of an extending surface of the glass or any position between them.

In contrast to the conventional encapsulation assembly for the functional glass, the encapsulation assembly 100 for the functional glass 201 according to embodiments of the present disclosure comprises a conductive module 102 arranged in the body 101 or on surfaces of the body 101 and electrically connected to the functional module.

By integrating the conductive module 102 electrically connected to the functional module into the body 101 of the encapsulation assembly 100, complicated wiring is no longer required when the functional module of the functional glass is connected, such that the functional glass can be mounted more conveniently to a desired position. Furthermore, since wiring is not needed any longer, problems such as wire breakage that may be caused during the assembly process are eliminated, such that stability of the functional module and the user experience can be improved.

In some embodiments, the conductive module 102 may comprise a conductive trace 1021 and a polymer matrix 1022. The conductive trace 1021 used herein may refer to any electrically connected metal wire or metal line, or any conductive line printed on the matrix. For example, in some embodiments, the conductive trace 1021 may be arranged on, for example, the polymer matrix 1022 by printing technology or the like. Then, the polymer matrix 1022 provided with the conductive trace 1021 may be attached to the encapsulation 101 during manufacturing of the encapsulation assembly 100 of the glass. In some embodiments, in order to facilitate attachment of the conductive module 102 to the body 101, the polymer matrix 1022 may be in the form of a film, i.e., the polymer matrix 1022 may be a polymer film.

Moreover, it should be appreciated that the embodiments where the conductive trace 1021 is arranged on the polymer matrix 1022 and then attached to the body 101 are merely for illustrative purposes, without suggesting any limitation as to the scope of the present disclosure, and any other appropriate manner is feasible. For example, in some alternative embodiments, the conductive trace 1021 is directly arranged at an appropriate position of the body 101 in an appropriate manner.

In some embodiments, the encapsulation assembly 100 may comprise an electronic part 103. The electronic part 103 is electrically connected to the functional module of the functional glass 201 via the conductive module 102. The electronic part 103 may be used to control functions of the functional module. The electronic part 103 may be of various forms, which will be further illustrated below.

It is to be understood that the embodiments where the encapsulation assembly 100 comprises an electronic part 103 is merely for illustrative purposes, without suggesting any limitation as to the scope of the present disclosure. Any other appropriate manner or arrangement is feasible. For example, in some other alternative embodiments, the encapsulation assembly 100 may not comprise an electronic part 103. For example, the conductive module 102 may be directly connected to a control system within an automobile and the like, to control various functions of the functional module.

In some embodiments, the electronic part 103 may be attached to the conductive module 102 before the conductive module 102 is attached to the body 101. For example, in some embodiments, the electronic part 103 may be arranged onto the polymer matrix 1022 with a conductive trace 1021 using a Surface Mount Technology (SMT). In some alternative embodiments, the electronic part 103 may be arranged onto the polymer matrix 1022 using a Dual In-line Package (DIP) technology. In this way, the electronic part 103 can be electrically connected to the functional module to allow a control of various functions of the function module.

Of course, it should be appreciated that the embodiments where the electronic part 103 may be attached to the conductive module 102 before the conductive module 102 is attached to the body 101 are merely for illustrative purposes, without suggesting any limitation as to the scope of the present disclosure. Any other appropriate process or arrangement is feasible. For example, in some alternative embodiments, in manufacturing processes of the encapsulated glass 200 or encapsulation assembly 100, after the body 101 to which the conductive module 102 is attached has been formed, the electronic part 103 can be attached to the body 101 using SMT, DIP, or the like. With this manufacturing process, the electronic part can be maintained or replaced conveniently in the event of a failure, thereby improving the maintenance efficiency.

As aforementioned, the body 101 may be a frame structure attached to the functional glass 201, to allow the functional glass 201 to be mounted at a desired position on a vehicle, an electronic device, or the like. In some embodiments, the body 101 may be formed around the functional glass 201 by injection molding, as shown in FIG. 1. For example, during the injection molding, the functional glass 201 and/or the electronic module 102 may be firstly arranged at appropriate positions in a mold, and then at least one of the following materials such as thermoplastic elastomer (TPE) material, a polyvinyl chloride (PVC) material or polyurethane (PU), acrylonitrile-butadiene-styrene plastic (ABS), polypropylene (PP), polyethylene terephthalate (PET), ethylene propylene rubber (EPDM), and a thermoplastic vulcanizate (TPV) material is injected into the mold to form the encapsulation assembly 100 of the glass.

It should be appreciated that at least one of the foregoing materials, as mentioned above, may refer to that two or more of those materials are injected into the mold sequentially or at different steps, to fulfill different functions such as sealing, securing, or the like. In some alternative embodiments, two or more of those materials may be injected into the mold after being mixed.

Of course, it should also be understood that the embodiments where the body 101 acts as the frame of the functional glass 201 are merely for illustrative purposes, without suggesting any limitation as to the scope of the present disclosure. Any other appropriate structure or arrangement is feasible. For example, in some alternative embodiments, the body 101 may be a film or bump structure arranged on the edges of the glass and provided with the conductive module 102. With this arrangement, the encapsulation assembly 100 of the glass, and even the encapsulated glass 200, can be applied to more occasions. For example, in some occasions where a frame structure is not required (i.e., only glass can be seen from the structural perspective), the glass with the body 101 (e.g., a film-like or bump-structured body) having the conductive module 102 can be directly mounted to the desired position.

In other words, the body 101 used herein may refer to any appropriate member for arranging the conductive module 102, and the body 101 may be formed integrally in the encapsulation assembly 100 of the glass during manufacturing of the encapsulation assembly 100 of the glass. Any appropriate body 101 meeting the above conditions is within the scope of the present disclosure.

The conductive module 102 may have an interface. The conductive trace 1021 may be coupled to the functional module via the interface and a connector or an interface circuit in the functional module. In this way, the electronic part 103 can control the functional module via the conductive trace 1021. Moreover, in order to fulfill the control, the conductive trace 1021 further comprises an interface coupled to an external power module (e.g., a power source), an external signal module or an electronic part 103, in some embodiments.

In some embodiments, the external signal module as mentioned herein may refer to an external control unit that can send a command signal to the electronic part 103 and/or receive a feedback signal from the electronic part 103. For example, when the encapsulation assembly 100 is applied to automobile glass, the external signal module may be a control unit on the automobile for controlling various functions of the automobile. Of course, in some alternative embodiments, the external signal module may be a sensor unit for sending a sensor signal or receiving a control signal. For example, the external signal module may also be a temperature sensor for sending a temperature signal to the electronic part 103 or a control unit of an automobile, to control the functions of the functional module. In addition, the interface coupled to the electronic part 103 may refer to a slot for facilitating insertion of the electronic part 103 such as a chip and the like.

The interface of the conductive module 102 and the functional module may be a connector or an interface circuit. For example, in some embodiments, the connector may be a two-pin socket allowing insertion of a plug of an external power source. In this way, the conductive module 102, the electronic part 103, and the external power module or external signal module can be electrically connected more conveniently. Of course, in some alternative embodiments, the interface may also be an interface circuit only, and the external power module or control module may be coupled to the interface circuit in an appropriate manner (e.g., SMT or the like). For example, the interface circuit may refer to a pin integrated with or electrically connected to the conductive trace 1021, to attain a higher integration and a much simpler structure.

Of course, it would be appreciated that, in addition to the wired connection as mentioned above, the interface may refer to a wireless connection interface. In other words, the interface may also communicate with the external power module or external signal modules in a wireless connection manner. For example, in some embodiments, the interface may implement wireless power transmission using an electromagnetic induction technology. In some alternative embodiments, the interface may implement transmission of data for controlling the functional module via Bluetooth, WiFi, or the like.

In some embodiments, in order to control the function module, a varying voltage signal needs to be applied to the functional module. For example, when a transparency of a Polymer Dispersed Liquid Crystal (PDLC) layer needs to be adjusted, it requires applying different voltages to the PDLC layer. In those embodiments, the electronic part 103 may at least comprise a microcontroller, and a Direct Current (DC-DC) converter or a Direct Current Alternating Current (DC-AC) and/or DC-variable DC converter. For example, the electronic part may be coupled to a direct current supplied from, for example, an external power module of an automobile power source. According to the need of the functional module, the microcontroller converts the input voltage to a desired voltage via a DC-DC converter, so as to output the voltage to the functional module via the interface and thus implement functions required by the functional module.

For example, the functional module may be a PDLC layer formed of an electrochromic material capable of electrochromic or changing transparency. The PDLC layer may be formed in the glass by laminating, and provided with an interface for the conductive module 102 to be coupled. In the meantime, the microcontroller may be coupled to an external control module or a sensor, i.e., an external signal module. Based on the signal of the external signal module, for example, a control signal from a user for lowering the transparency of the glass, or a sensor signal from the sensor that indicates that temperature is higher than a predetermined value, the microcontroller controls the DC-DC converter to convert the input voltage to a voltage value that causes the transparency of the PDLC layer to decrease to control the PDLC layer, thereby fulfilling the desired function.

Of course, it should be appreciated that the embodiments on the DC-DC converter are merely for illustrative purposes, without suggesting any limitation as to the scope of the present disclosure. Any other appropriate converter is feasible. For example, in some alternative embodiments, the electronic part may also comprise a DC-AC converter or DC-variable DC converter. In some alternative embodiments, when the input is alternating current (AC), the electronic part may include an AC-DC converter or AC-AC converter.

In addition to the microcontroller and the voltage converter, the electronic part 103 may also comprise a bus transceiver for transmitting a signal, such as a control signal or sensor signal. For example, in cases where the glass is automobile glass, the bus transceiver may comprise a Controller Area Network (CAN) transceiver and/or Local Interconnect Network (LIN) bus transceiver. With this arrangement, the electronic part can be connected to a control system of the automobile via a CAN bus and/or LIN bus, to fulfill additional functions. For example, a user can control the transparency or the like by voice via the control system of the automobile.

Of course, it should be understood that the embodiments about the devices included in the electronic part 103 are merely for illustrative purposes and not exhaustive, which are not intended to limit the scope of the present disclosure. Any other appropriate device or module is feasible. For example, in the embodiments where the functional module includes a display layer, the electronic part 103 may also comprise a display control chip for controlling display of the display layer; optionally, in some other alternative embodiments, in cases where the functional module provides a touch function, the electronic part 103 may also comprise a touch chip or the like.

According to another aspect of the present disclosure, there is provided encapsulated glass 200. The encapsulated glass 200 is formed by attaching the encapsulation assembly 100 as mentioned above to the functional glass 201 in an appropriate manner (e.g., by injection molding). As aforementioned, the functional glass 201 may be laminated glass, i.e., the functional module is located between two layers of glass. In some alternative embodiments, the functional glass 201 may also be tempered glass, and the functional module is attached to a surface of the glass. The encapsulated glass 200 according to the embodiments of the present disclosure brings about convenient and easy mounting of glass, such as automobile glass or the like, and thus reduces the mounting cost.

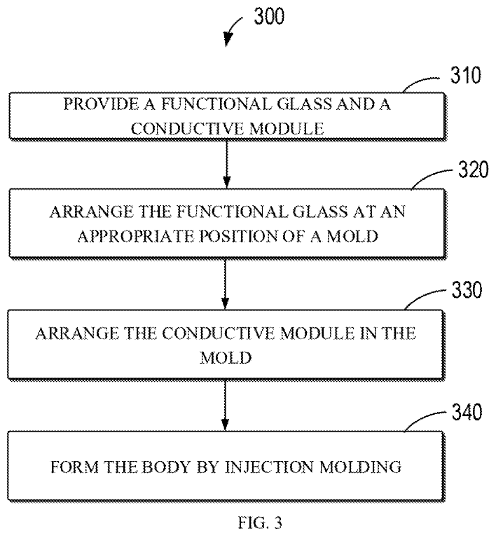

According to a further aspect of the present disclosure, there is provided a manufacturing method of encapsulated glass 200. FIG. 3 illustrates a flowchart of a manufacturing method of encapsulated glass 200 according to embodiments of the present disclosure. As shown in FIG. 3, at block 310, functional glass 201 and a conductive module 1011 are provided. The conductive module 1011 is electrically connected to a functional film in the functional glass 201.

At block 320, the functional glass 201 is arranged at an appropriate position in a mold. For example, in cases where the body 101 is a frame structure surrounding the functional glass, the mold for forming the body 101 may surround the functional glass 201. Next at block 330, the conductive module 102 is arranged in the mold so that the conductive module 102 is subsequently embedded in the body 101 formed by injection molding or located on a surface of the body 101 formed by injection molding. At block 340, the body 101 is formed by injection molding, where at least a part of the conductive module 102 needs to be coupled to the interface of the functional module in the functional glass 201 to facilitate subsequent control of the functional module.

In some embodiments, the conductive module 102 may be obtained by pre-arranging the conductive trace 1021 on the polymer matrix 1022. In some embodiments, on the polymer matrix 1022 formed with the conductive trace 1021, the electronic part 103 may be attached to the polymer matrix 1022 through SMT or the like to electrically connect to the conductive trace 1021. Thereafter, the polymer matrix 1022 provided with the conductive trace 1021 and the electric part 103 is arranged at an appropriate position in the mold. Subsequently, the body 101 is formed by injection molding to embed the conductive module 102 and the electronic part 103 together in the body 101. Embedding the conductive module 102 and the electronic part 103 together in the body 101 makes the encapsulation assembly 100 more integrated and easier to maintain and assemble.

In some embodiments, the polymer matrix 1022 (such as a film) provided with a conductive trace 1021 may be directly arranged in an appropriate position of the mold, and then the body 101 is formed. Thereafter, the electronic part 103 is attached to the body 101 to electrically connect to the conductive trace 1021.

As can be seen from the above description, by forming encapsulated glass 201 from the encapsulation assembly 100 for functional glass 201 according to embodiments of the present disclosure, the complicated manufacturing steps and materials can be eliminated and thus the costs can be reduced. An easy and stable control of the functional module in the functional glass 201 can also be accomplished. Moreover, it is much easier to form encapsulated glass 200 from functional glass 201 to facilitate glass mounting.

It should be appreciated that the above description of the various embodiments of the present disclosure have been presented for purposes of illustration or explanation about principles of the present disclosure, without suggesting limitations to the present disclosure. Hence, any modification, equivalent substitution, improvement, and the like, within the spirit and principles of the present disclosure shall fall into the protection scope of the present disclosure. Furthermore, the appended claims are intended to cover all changes and modifications falling into the scope and boundaries equivalent to the scope and boundary thereof.

1. An encapsulation assembly for a functional glass, comprising:
a body located at edges of the functional glass; and
a conductive module embedded in the body or located on a surface of the body, and electrically connected to a functional module on the functional glass.

2. The encapsulation assembly of claim 1, wherein the conductive module comprises a conductive trace and a polymer matrix, the conductive trace is formed on the polymer matrix.

3. The encapsulation assembly of claim 1, wherein the conductive module comprises an interface coupled to the functional module, an external power module, an external signal module, and/or an electronic part.

4. The encapsulation assembly of claim 3, wherein the interface comprises a connector or an interface circuit.

5. The encapsulation assembly of claim 1, further comprising an electronic part electrically connected to the functional module via the conductive module to allow a control of functions of the functional module.

6. The encapsulation assembly of claim 5, wherein the electronic part is arranged on the body or the polymer matrix through a Surface Mount Technology or a Dual In-line Packaging technology to be electrically connected with the conductive trace.

7. The encapsulation assembly of claim 5, wherein the electronic part comprises at least one of the followings: a microcontroller, a voltage converter, and/or a bus transceiver.

8. The encapsulation assembly of claim 7, wherein the voltage converter comprises a Direct Current converter or a Direct Current Alternating Current converter.

9. The encapsulation assembly of claim 7, wherein the bus transceiver comprises at least one of a controller area network bus transceiver and a local interconnection network bus transceiver.

10. The encapsulation assembly of claim 1, wherein the body is formed by injection molding.

11. The encapsulation assembly of claim 1, wherein the body is made of at least one of a thermoplastic elastomer (TPE) material, a polyvinyl chloride (PVC) material or a polyurethane (PU), Acrylonitrile-butadiene-styrene plastic (ABS), a polypropylene (PP), a polyethylene terephthalate (PET), an ethylene propylene rubber (EPDM), and a thermoplastic vulcanizate (TPV) material.

12. An encapsulated glass, comprising:
a functional glass comprising a functional module arranged therein or thereon; and
an encapsulation assembly of claim 1, attached to the functional glass to form the encapsulated glass.

13. The encapsulated glass of claim 12, wherein the functional module is used to provide at least one of the following functions: color change, transparency adjustment, lighting, display, touch, photovoltaic power generation, heating or communication.

14. A manufacturing method of an encapsulated glass, comprising:
providing a functional glass and a conductive module, the functional glass comprising a functional module, and the conductive module used for electrical connection with the functional module;
arranging the functional glass at an appropriate position of a mold;
arranging the conductive module in the mold so as to be subsequently embedded in a body formed by injection molding or located on a surface of the body formed by injection molding; and
forming the body by injection molding.

15. The manufacturing method of claim 14, wherein the step of providing the conductive module comprises forming a conductive trace on a polymer matrix.

16. The manufacturing method of claim 14, further comprising, before forming the body at edges of the glass, electrically connecting an electronic part with the conductive module.

17. The manufacturing method of claim 14, further comprising, after forming the body at edges of the glass, electrically connecting an electronic part with the conductive module.
